(19) United States
(12) Patent Application Publication
(10) Pub. No.: US 2020/0235547 A1
(43) Pub. Date: Jul. 23, 2020

(54) OPTICAL TRANSMITTER

(71) Applicant: PHOTONICS ELECTRONICS TECHNOLOGY RESEARCH ASSOCIATION, Tokyo (JP)

(72) Inventor: Kenji Mizutani, Tokyo (JP)

(21) Appl. No.: 16/087,961

(22) PCT Filed: Mar. 29, 2017
(86) PCT No.: PCT/JP2017/012878

§ 371 Date: Sep. 24, 2018

(30) Foreign Application Priority Data
Mar. 30, 2016 (JP) 2016-067789

(51) Int. Cl. H01S 5/00; H04B 10/50; H04B 10/61; G02B 6/42

(52) U.S. Cl. CPC H01S 5/0085; G02B 6/4215; H04B 10/61; H04B 10/503

(57) ABSTRACT

Provided is an optical transmitter in which a forward-end surface of a semiconductor laser is set to an effective reflectance with respect to near-end reflection. The optical transmitter is provided with a semiconductor laser and at least one optical function element to which output light from the semiconductor laser is input. The optical transmitter is characterized in that: a signal-to-noise ratio in an optical receiver which receives an optical signal output from the optical transmitter includes a first contribution component caused by re-entry of reflected return light from the at least one optical function element into the semiconductor laser, and a second contribution component caused irrespective of the strength of the optical signal input to the optical receiver; and the reflectance of a forward-end surface of the semiconductor laser is set to a value in a predetermined range including a reflectance that maximizes the signal-to-noise ratio due to the first contribution component and the second contribution component with respect to a change in the reflectance of the forward-end surface.

### TECHNICAL FIELD

The present invention relates to an optical transmitter.

### BACKGROUND ART

In prior art, an optical transmitter in which a semiconductor laser and a silicon photonics circuit are hybridly integrated, has been known, wherein the silicon photonics circuit comprise a modulator and a waveguide on a silicon substrate (for example, refer to Non-Patent Literatures 1-3). In such an optical transmitter, light from a semiconductor laser is inputted to a modulator via a waveguide, and an optical signal modulated by the modulator is outputted from the optical transmitter.

In general, in a laser light source such as a semiconductor laser or the like, there is a problem that laser oscillation becomes unstable, when part of output light is reflected in an optical path and returned as return light into a laser medium. In prior art, for solving the above problem, a reflectance of a front-end surface (an end surface of an emitting side) of a semiconductor laser is set to an appropriate value (for example, refer to Non-Patent Literatures 1-3).

### CITATION LIST

### Patent Literature

PTL 1: Japanese Patent Application Public Disclosure No. 2006-128475

PTL 2: Japanese Patent Application Public Disclosure No. H10-022565

PTL 3: Japanese Patent Application Public Disclosure No. H09-064460

### Non Patent Literature

NPL 1: Yutaka Urino et al., “First Demonstration of Athermal Silicon Optical Interposers With Quantum Dot Lasers Operating up to 125° C.,” Journal of Lightwave Technology, Vol. 33, No. 6, March 2015, pp. 1223-1229

NPL 2: Kenji Mizutani et al., “Isolator Free Optical I/O Core Transmitter by using Quantum Dot Laser,” Proceeding of the Group IV Photonics 2015, 2015, pp. 177-178

NPL 3: Kenji Mizutani et al., “Optical I/O Core Transmitter with High Tolerance to Optical Feedback using Quantum Dot Laser,” Proceeding of the European Conference on Optical Communication 2015, 2015, P. 4.7

NPL 4: L. A. Coldren et al., “Diode Lasers and Photonic Integrated Circuits,” 5.7, Wiley Series in Microwave and Optical Engineering, p. 251, Formula (5-180)

### SUMMARY OF INVENTION

### Technical Problem

In Patent Literatures 1-3, optimization of a reflectance of a front-end surface is attempted for the purpose of improvement of performance of a semiconductor laser unit. However, in an optical transmitter wherein a silicon photonics circuit is hybridly integrated with a semiconductor laser, laser oscillation is severely affected by reflected return light. There are two reasons thereof, and the first reason is that it is not possible to arrange, at a position near a semiconductor laser, an optical isolator for cutting reflected return light. Another reason is that, in a hybrid integrated optical transmitter, a main reflection point of laser output light is positioned within the same integrated substrate, i.e., positioned at a place very close to the semiconductor laser (the so-called near-end reflection), thus, coherence of the reflected return light is high and, in addition thereto, polarization is maintained. Accordingly, it is necessary to take a problem such as that described above, which is specific to a hybrid integrated optical transmitter, into consideration, and set a reflectance of a front-end surface of a semiconductor laser.

The present invention has been achieved in view of the above matters; and an object of the present invention is to provide an optical transmitter in which a reflectance of a front-end surface of a semiconductor laser is set to be effective with respect to near-end reflection.

### Solution to Problem

For solving the above problem, an embodiment of the present invention is an optical transmitter which is characterized in that it comprises a semiconductor laser and at least one optical function element to which light outputted from the semiconductor is inputted; and that a signal-to-noise ratio in an optical receiver, which receives an optical signal outputted from the optical transmitter, comprises a first contributing component which is generated as a result of re-incidence of reflected return light on the semiconductor laser from the at least one optical function element, and a second contributing component which is generated independent of intensity of an optical signal inputted to the optical receiver; and a reflectance of a front-end surface of the semiconductor laser is set to a value within a predetermined range which includes a reflectance which maximizes, in relation to change in the reflectance, the signal-to-noise ratio, which is based on the first contributing component and the second contributing component.

Further, another embodiment of the present invention is characterized in that it comprises the above embodiment, and a gain region of the semiconductor laser comprises quantum dots.

Further, another embodiment of the present invention is characterized in that it comprises the above embodiment, and the reflectance of the front-end surface of the semiconductor laser is 2-25%.

Further, another embodiment of the present invention is characterized in that it comprises the above embodiment, and the quantity of the reflected return signal, which is re-incident on the semiconductor laser, is less than 1.

Further, another embodiment of the present invention is characterized in that it comprises the above embodiment which comprises a refractive index adjusting agent put between the front-end surface of the semiconductor laser and the at least one optical function element.

Further, another embodiment of the present invention is characterized in that it comprises the above embodiment, and the semiconductor laser and the at least one optical function element are integrated on a silicon substrate.

### ADVANTAGEOUS EFFECTS OF INVENTION

According to the present invention, an optical transmitter, in which a reflectance of a front-end surface of a semiconductor laser is set to be effective with respect to near-end reflection, can be provided.

### BRIEF DESCRIPTION OF DRAWINGS

FIG. 1 is a cross-sectional structure view of an optical transmitter 100 according to an embodiment of the present invention.

FIG. 2 shows an optical transmission system 400 which uses the optical transmitter 100 according to an embodiment of the present invention.

FIG. 3 is an example graph showing relationship between the reflectance R of a front-end surface of a semiconductor laser 140 and the overall signal-to-noise ratio SNR_{PD_total} of an optical receiver 200.

FIG. 4 is a graph showing relationship between the total optical loss Lₜₒₜₐₗ of the optical transmission system 400 and the range of reflectance R within which the signal-to-noise ratio SNR_{PD_total} becomes 23 dB or more than 23 dB.

FIG. 5 is a graph showing relationship between the total optical loss Lₜₒₜₐₗ of the optical transmission system 400 and the output power P_{LDout} of the semiconductor laser 140 required for making the maximum value of the signal-to-noise ratio SNR_{PD_total} to be 23.1 dB.

FIG. 6 is a cross-sectional structure view of an optical transmitter 101 according to a modified embodiment.

### DESCRIPTION OF EMBODIMENTS

In the following description, embodiments of the present invention will be explained in detail, with reference to the figures.

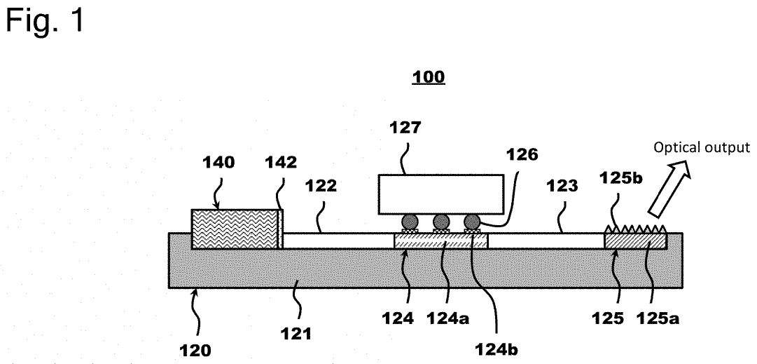

FIG. 1 is a cross-sectional structure view of an optical transmitter 100 according to an embodiment of the present invention. The optical transmitter 100 comprises a silicon photonics circuit 120, and a semiconductor laser 140 that is hybridly integrated on the silicon photonics circuit 120. The silicon photonics circuit 120 comprises optical waveguides 122 and 123, an optical modulator 124, and a grating coupler 125, which are formed on a silicon substrate 121. An emitting-side end surface of the semiconductor laser 140 is optically coupled to one end of the optical waveguide 122, and another end of the optical waveguide 122 is optically coupled to an input-side end of the optical modulator 124. An output-side end of the optical modulator 124 is optically coupled to one end of the optical waveguide 123, and another end of the optical waveguide 123 is optically coupled to an input end of the grating coupler 125.

The construction of each of the optical waveguides 122 and 123, the optical modulator 124, and the grating coupler 125 has been well known, and should not be considered to be limiting the scope of the present invention.

For example, each of the optical waveguides 122 and 123 may have a construction which comprises a lower-side cladding layer comprising a buried oxide film (BOX layer) formed on the silicon substrate 121, a core layer comprising a silicon thin film layer formed on the buried oxide film layer, and an upper-side cladding layer formed on the silicon thin film layer. Alternatively, each of the optical waveguides 122 and 123 may have a construction in which a core layer, an upper-side cladding layer, and a lower-side cladding layer are formed on the silicon substrate 121 by use of oxide films. The optical modulator 124 may have a construction in which metal thin film electrodes 124b are formed on an optical waveguide 124a for changing a refractive index of the optical waveguide 124a by applying an electric field thereto, wherein the optical waveguide 124a comprises a construction similar to those of the optical waveguides 122 and 123. As shown in the figure, a driver IC 127 is put on the optical modulator 124 via connection electrodes 126. The driver IC 127 supplies a modulation signal to the metal thin film electrodes 124b of the optical modulator 124; and, in response to the modulation signal, the light propagating through the optical waveguide 124a of the optical modulator 124 is modulated. The gating coupler 125 may have a construction in which a periodic concavity and convexity structure 125b is formed on a surface of an optical waveguide 125a which comprises a construction similar to those of the optical waveguides 122 and 123, for example.

The semiconductor laser 140 may apply a Fabry-Perot laser or a distributed feedback laser, for example. Further, a gain region of the semiconductor laser may be constructed by use of quantum dots or a quantum well. Preferably, a Fabry-Perot quantum-dot laser is used as the semiconductor laser 140.

The light outputted from the output-side end surface of the semiconductor laser 140 is inputted to the optical modulator 124 via the optical waveguide 122, and, in the optical modulator 124, the light is modulated according to the modulation signal supplied from the driver IC 127. The light modulated by the optical modulator 124 is inputted to the grating coupler 125 via the optical waveguide 123, and refracted toward a predetermined direction by the grating coupler 125 for outputting the light from the optical transmitter 100 to an external waveguide (which is not shown in the figure). In this embodiment, by using a silicon waveguide which is appropriate for the purpose of miniaturization, the length from the output end of the semiconductor laser 140 to the grating coupler 125 is made to be approximately 5 mm.

A part of the light outputted from the semiconductor laser 140 is reflected at a reflection point existing within the optical transmitter 100, and the reflected part of the light is thereby turned into return light which is directed toward the semiconductor laser 140. For example, in the optical transmitter, the grating coupler 125 may be a reflection point which causes strong reflection. The front-end surface (emitting-side end surface) of the semiconductor laser 140 is provided with a dielectric film 142 for preventing or reducing destabilization of laser oscillation of the semiconductor laser 140 due to such reflected return light. By the dielectric film 142, the reflectance of the front-end surface of the semiconductor laser 140 is defined. As explained above, in the case that near-end reflection such as that occurring at a reflection point within the optical transmitter 100 exists, it is necessary to set the reflectance of the front-end surface of the semiconductor laser 140 by taking effect of the near-end reflection into consideration. In the following description, the optimum reflectance of the front-end surface of the semiconductor laser 140 in the optical transmitter 100 will be explained.

First, the quantity of the reflected return light re-entering the semiconductor laser 140, C_{feedback}, is represented by following formula (1).

$$\begin{matrix}[ Formula 1 ] & \\ {C}_{feedback} = \frac{{t}^{2}}{r} \cdot \sqrt{α} \cdot \frac{{τ}_{ext}}{{τ}_{LD}} & ( 1 )\end{matrix}$$

In the above formula, r and t are an amplitude reflectance and an amplitude transmittance at the front-end surface of the semiconductor laser 140, respectively; and they satisfy relationship r²+t²=1.α(=P_{feedback}/P_{LDout}) is a ratio of the reflected return light power P_{feedback} to the output power P_{LDout} of the semiconductor laser 140, and is a value which is determined based only on an optical loss in the round trip path between the front-end surface (emitting-side end surface) of the semiconductor laser 140 and the reflection point, and on the reflectance of the reflection point. τ_{LD} is travel time of the light in the path between the rear end and the front end of the semiconductor laser 140, and is a value which is determined based on the waveguide structure (the shape and the refractive index) of the semiconductor laser 140. τₑₓₜ is travel time of the light in the path between front-end surface of the semiconductor laser 140 and the reflection point. In this embodiment, the reflection from the grating coupler 125, which has a grating structure which makes it difficult to suppress reflection, is large, specifically, approximately −20 dB (1%); thus, the travel time τₑₓₜ is determined based on the waveguide structure of each of the waveguides 122 and 123, the optical modulator 124, and the grating coupler 125. Formula (1) shows that the quantity C_{feedback} of the reflected return light in the semiconductor laser 140 is a function of the amplitude reflectance r of a light wave at the front-end surface of the semiconductor laser 140.

It is possible to experimentally derive a signal-to-noise ratio SNR_{LD} of the semiconductor laser 140 from the quantity C_{feedback} of the reflected return light in the semiconductor laser 140. Formula (2) is an example of a relation expression.

[Formula 2]

SNR_{LD}[dB]=−0.5·C_{feedback}[dB]+46 (2)

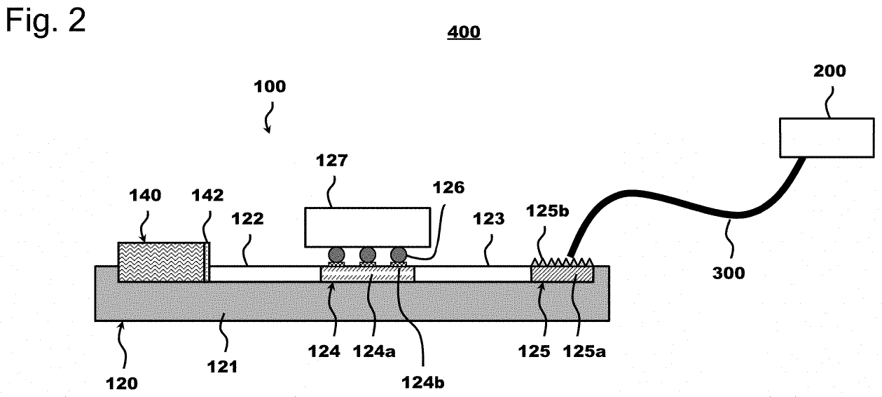

As shown in FIG. 2, it is supposed that there is an optical transmission system 400 in which an optical signal from the optical transmitter 100 according to the present embodiment is transmitted via a transmission path 300 and received by an optical receiver 200. The signal-to-noise ratio SNR_{PD} of the optical receiver 200 (effect due to thermal noise and so on of the optical receiver 200 are excluded) is represented by use of the signal-to-noise ratio SNR_{LD} of the semiconductor laser 140, as shown by formula (3).

[Formula 3]

SNR_{PD}[dB]=SNR_{LD}[dB]+PN_{Link}[dB]+Lₜₒₜₐₗ[dB] (3)

In the above formula, PN_{Link} is a transmission penalty which is applied to signal strength, wherein the transmission penalty is that applied as a result of deterioration of waveform on a time axis due to dispersion and so on in the transmission path 300 (an optical fiber) of the optical transmission system 400; and Lₜₒₜₐₗ is a total optical loss from the semiconductor laser 140 of the optical transmitter 100 to the optical receiver 200. As shown in following formula (4), the total optical loss Lₜₒₜₐₗ from the semiconductor laser 140 to the optical receiver 200 includes an insertion loss Lᵢₙₛ from the semiconductor laser 140 to the silicon photonics circuit 120 (the optical waveguide 122), a propagation loss Lₚᵣₒₚ in the silicon photonics circuit 120 (the optical waveguide 122, the optical modulator 124, and the optical waveguide 123), a coupling loss L_{GC} from the optical waveguide 123 to the grating coupler 125, and a propagation loss L_{Link} of the transmission path 300. Note that the insertion loss Lᵢₙₛ includes a loss due to an extinction characteristic of modulation in the optical modulator 124.

[Formula 4]

Lₜₒₜₐₗ[dB]=Lᵢₙₛ[dB]+Lₚᵣₒₚ [dB]+L_{GC}[dB]+L_{Link}[dB] (4)

Optical modulation amplitude, OMA_{PD}, of an optical signal received by the optical receiver 200 can be derived, according to following formula (5), on the basis of the output power P_{LDout} of the semiconductor laser 140 and the total optical loss Lₜₒₜₐₗ of the optical transmission system 400.

[Formula 5]

OMA_{PD}[dBm]=P_{LDout}[dBm]−Lₜₒₜₐₗ[dB] (5)

The output power P_{LDout} of the semiconductor laser 140 can be calculated by use of a variety of parameters relating to the structure of the semiconductor laser 140 (the material and the shape of each of an active layer, a cladding later, an electrode, and so on, reflectivity of each of the front-end surface and the rear-end surface, and so on), the value of current for driving the semiconductor laser 140, and so on. The output power P_{LDout} of the semiconductor laser 140 is a function of the reflectance R (=r²) of the front-end surface of the semiconductor laser 140; and, it is possible to obtain from following formula (6), in an simplified manner, the output power P_{LDout}(R) as a function of an arbitrary reflectance R, by using, for example, the output power P_{LDout}(30%) that is numerically calculated with respect to a specific reflectance value of R=30%.

$$\begin{matrix}[ Formula 6 ] & \\ \begin{matrix}{P}_{L D o u t} [ dBm ] = {P}_{LDout} ( R ) [ dBm ] \\ = {P}_{LDout} ( 30 \% ) [ dBm ] + 10 \cdot log ( \frac{100 - R}{70} )\end{matrix} & ( 6 )\end{matrix}$$

By use of the signal-to-noise ratio SNR_{PD} and the optical modulation amplitude OMA_{PD} of the optical receiver 200 shown in formula (3) and formula (5), an optical noise σₒₚₜ in the optical receiver 200 is represented by following formula (7).

$$\begin{matrix}[ Formula 7 ] & \\ {σ}_{opt} [ W ] = \sqrt{\frac{{( 1 {0}^{{OMA}_{PD} [ dBm ] / 10} \cdot 0.001 )}^{2}}{1 {0}^{{SNR}_{PD} [ dB ] / 10}}} & ( 7 )\end{matrix}$$

The optical noise σₒₚₜ in formula 7 originates from light outputted from the semiconductor laser 140. In the optical receiver 200, non-optical noise σₙₒₙ₋ₒₚₜ, which is due to thermal noise and so on and does not depend on the optical signal, exists additionally. The non-optical noise σₙₒₙ₋ₒₚₜ can be experimentally estimated. For example, the higher the transmission speed, the larger the non-optical noise σₙₒₙ₋ₒₚₜ; but the non-optical noise σₙₒₙ₋ₒₚₜ is constant for determined transmission speed. When both the optical noise σₒₚₜ and the non-optical noise σₙₒₙ₋ₒₚₜ are taken into consideration, the total noise σₜₒₜₐₗ in the optical receiver 200 is given by following formula (8); and, by use of the total noise σₜₒₜₐₗ, the overall signal-to-noise ratio SNR_{PD_total} in the optical receiver 200 is represented by following formula (9).

$$\begin{matrix}[ Formula 8 ] & \\ {σ}_{total}^{2} [ W ] = {σ}_{opt}^{2} + {σ}_{non \text{-} opt}^{2} & ( 8 ) \\ [ Formula 9 ] & \\ {SNR}_{PD \_ total} [ dB ] = 10 \cdot log \{ \frac{{( 1 {0}^{{OMA}_{PD} [ dBm ] / 10} \cdot 0.001 )}^{2}}{{σ}_{total}^{2}} \} & ( 9 )\end{matrix}$$

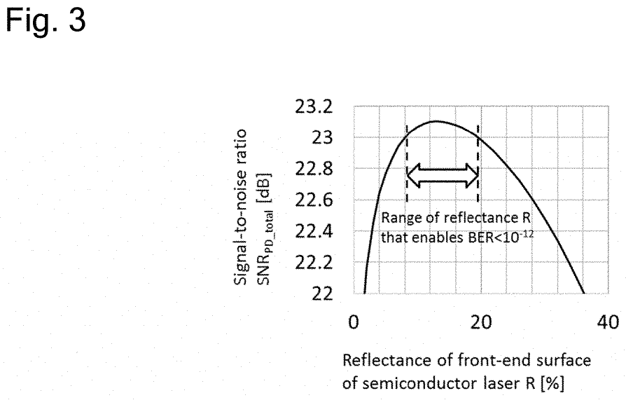

It can be understood from formula (9) and the process of deriving formula (9), that the overall signal-to-noise ratio SNR_{PD_total} in the optical receiver 200 is a function of the reflectance R (or the amplitude reflectance r) of the front-end surface of the semiconductor laser 140. FIG. 3 is an example graph showing relationship between the reflectance R of the front-end surface of the semiconductor laser 140 (the horizontal axis) and the overall signal-to-noise ratio SNR_{PD_total} of the optical receiver 200 (the vertical axis) calculated according to formula (9). In FIG. 3, the value of the overall signal-to-noise ratio SNR_{PD_total} of the optical receiver 200 becomes the maximum when the reflectance R of the front-end surface of the semiconductor laser 140 is approximately 13%, and the signal-to-noise ratio SNR_{PD_total} is lowered as the reflectance R decreases or increases. This is because in case of decreased reflectance R of the front-end surface of the semiconductor laser 140, the reflected light is easily injected back into the semiconductor laser 140, causing unstable laser oscillation (i.e., a first contribution to the signal-to-noise ratio SNR_{PD_total}); and, on the other hand, in case of increased reflectance R, the output power P_{LDout} of the semiconductor laser 140 is lowered, causing relatively large effect of thermal noise in the optical receiver 200, and crosstalk in wavelengths when the optical transmitter 100 is used in a wavelength division multiplexing system (i.e., a second contribution to the signal-to-noise ratio SNR_{PD_total}).

In the optical receiver 200, for achieving a bit error rate equal to or less than 10⁻¹², which corresponds to an error-free system, the overall signal-to-noise ratio SNR_{PD_total} needs to be equal to or more than 23 dB. In the case of FIG. 3, it can be understood that the above condition is satisfied when the reflectance R of the front-end surface of the semiconductor laser 140 is in the range of approximately 8-20% (shown by an arrow in the figure). Note that, in the graph shown in FIG. 3, the value of the output power P_{LDout} of the semiconductor laser 140 is set in such a manner that the maximum value of the signal-to-noise ratio SNR_{PD_total} becomes 23.1 dB.

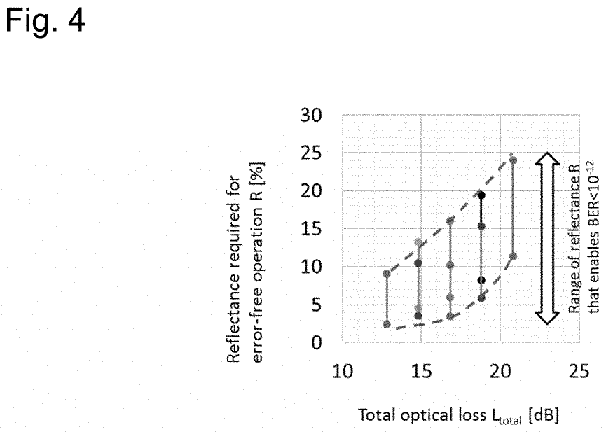

The relationship between the reflectance R of the front-end surface of the semiconductor laser 140 and the overall signal-to-noise ratio SNR_{PD_total} of the optical receiver 200 changes from that shown in FIG. 3, when any of the various variables appearing in the above formulas is/are changed. Further, in response to change in the relationship between the reflectance R and the signal-to-noise ratio SNR_{PD_total}, the range of the reflectance R for which the signal-to-noise ratio SNR_{PD_total} is ensured to be equal to or more than 23dB also changes. FIG. 4 is a graph showing the range of reflectance R of the front-end surface of the semiconductor laser 140 within which the overall signal-to-noise ratio SNR_{PD_total} of the optical receiver 200 is equal to or more than 23 dB (the vertical axis), versus various values of the total optical loss Lₜₒₜₐₗ (refer to formula (4)) from the semiconductor laser 140 to the optical receiver 200 (the horizontal axis). In the optical transmission system 400 in the present embodiment, the lower limit of the total optical loss Lₜₒₜₐₗ (approximately 13 dB in FIG. 4) is restricted by the condition that multi-mode laser oscillation due to reflected return light from a reflection point external to the semiconductor laser 140 does not occur, that is, laser oscillation by an external oscillator formed by the external reflection point and the rear-end surface of the semiconductor laser 140 does not occur. In the case that a quantum dot laser, in which linewidth enhancement factor theoretically becomes 0, is used as the semiconductor laser 140, the above condition is equivalent to satisfying C_{feedback}<1, where C_{feedback} is an the quantity of the reflected return light within the semiconductor laser 140, which is represented by formula (1) (refer to NPL 4). Further, the upper limit of the total optical loss Lₜₒₜₐₗ (approximately 21 dB in FIG. 4) is determined such that the load for driving the semiconductor laser 140 when the loss increases does not become excessively large.

As shown in FIG. 4, the range of the optimum reflectance R of the front-end surface of the semiconductor laser 140 is lowered, as the total optical loss Lₜₒₜₐₗ of the optical transmission system 400 becomes smaller. It can be understood from FIG. 4 that, for maintaining the overall signal-to-noise ratio SNR_{PD_total} of the optical receiver 200 to be equal to or more than 23 dB even if the total optical loss Lₜₒₜₐₗ of the optical transmission system 400 changes between the upper limit and the lower limit thereof, the reflectance R of the front-end surface of the semiconductor laser 140 should be set to a value within the range of approximately 2-25% (shown by an arrow in the figure).

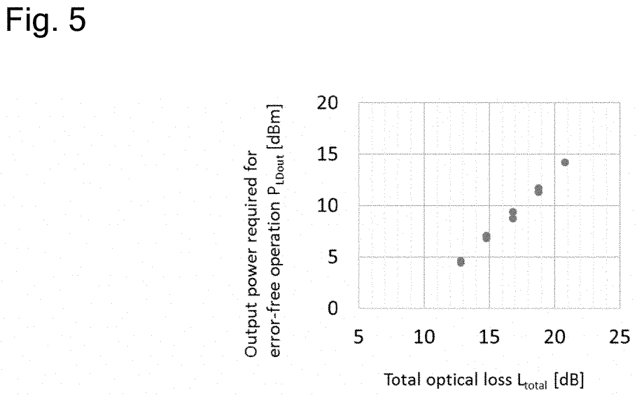

FIG. 5 is a graph showing relationship between the total optical loss Lₜₒₜₐₗ of the optical transmission system 400 (the horizontal axis) and the output power P_{LDout} of the semiconductor laser 140 required for making the maximum value of the overall signal-to-noise ratio SNR_{PD_total} of the optical receiver 200 to be 23.1 dB (in a manner similar to that of the graph shown in FIG. 3) (the vertical axis). As shown in FIG. 5, it can be understood that the output power P_{LDout} of the semiconductor laser 140 required for obtaining a bit error rate equal to or less than 10⁻¹² becomes smaller, as the total optical loss Lₜₒₜₐₗ becomes smaller. Thus, it is possible to achieve both high-quality optical transmission characteristics and power saving in the semiconductor laser 140 at the same time, by lowering loss (the insertion loss Lᵢₙₛ, the propagation loss Lₚᵣₒₚ, and the coupling loss L_{GC}) of the optical elements in the optical transmitter 100. Further, assuming that the reflectance of a front-end surface of a semiconductor laser is approximately 30% in a prior-art construction, the output power P_{LDout} of the semiconductor laser 140 can be reduced, compared with the prior-art construction, to approximately 1 dB, by applying, to the optical transmitter 100, the semiconductor laser 140 having the range of the reflectance R such as that explained in relation to the present embodiment, thus, power-saved operation can be performed. Further, since it is possible to obtain high-quality transmission characteristics without using an optical isolator, miniaturization and cost reduction of the optical transmitter 100 can be realized.

The embodiment of the present invention has explained in the above description; and, in this regard, the present invention is not limited by the above embodiment, and the embodiment can be modified in various ways without departing the scope of the gist of the present invention.

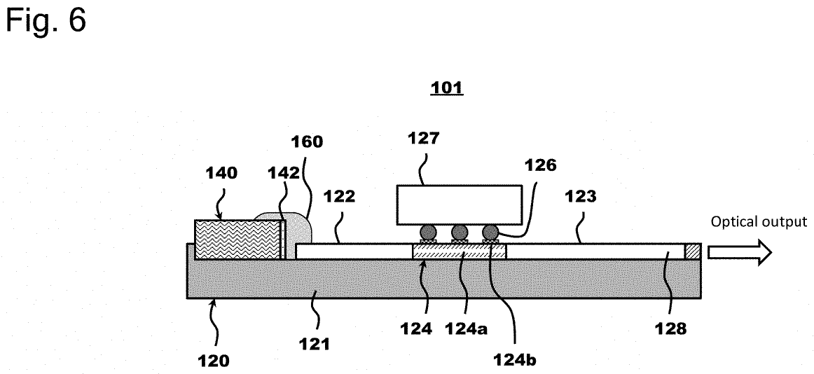

FIG. 6 is a cross-sectional structure view of an optical transmitter 101 in a modified embodiment. The optical transmitter 101 comprises a refractive index adjusting agent 160 in a space between a dielectric film 142 of a front-end surface of a semiconductor laser 140 and an end part, at the semiconductor laser 140 side, of an optical waveguide 122. The refractive index adjusting agent 160 is an optical medium (which may be in the form of fluid, for example) for controlling reflection due to difference between a reflectance of the dielectric film 142 of the front-end surface of a semiconductor laser 140 and a reflectance of the optical waveguide 122. In the optical transmitter 101, an optical layer comprising the dielectric film 142 and the refractive index adjusting agent 160 defines an effective reflectance at the front-end surface of the semiconductor laser 140. For example, the reflectance at the front-end surface of a semiconductor laser 140, in a structure where the dielectric film 142 only is provided, is set to 30% or more than 30%; and the reflectance at the front-end surface of a semiconductor laser 140, in a structure where both the dielectric film 142 and the refractive index adjusting agent 160 are provided, is set to a value similar to that of the aforementioned optical transmitter 100 shown in FIG. 1 (2-25%, for example).

Note that, as shown in FIG. 6, the optical transmitter 101 may be constructed in such a manner that a spot size converter 128 is adopted in place of a grating coupler 125, for improving efficiency of optical coupling with an external waveguide (not shown in the figure).

Further, regarding a semiconductor laser 140, it is possible to use a construction wherein a semiconductor gain element is attached onto an integrated substrate (a silicon substrate 121) and coupled to an optical waveguide 122, or a construction wherein a semiconductor gain element itself is integrated.

### REFERENCE SIGNS LIST

100, 101 Optical transmitter

120 Silicon photonics circuit

121 Silicon substrate

122, 123 Optical waveguide

124 Optical modulator

124a Optical waveguide

124b Metal thin film electrode

125 Grating coupler

125a Optical waveguide

125b Concavity and convexity structure

126 Connection electrode

127 Driver IC

128 Spot size converter

140 Semiconductor laser

142 Dielectric film

160 Refractive index adjusting agent

200 Optical receiver

300 Transmission path

400 Optical transmission system

1. An optical transmitter comprising:
a semiconductor laser; and
at least one optical function element to which light outputted from the semiconductor laser is inputted,
wherein a signal-to-noise ratio in an optical receiver receiving an optical signal outputted from the optical transmitter, comprises a first contributing component and a second contributing component, wherein the first contributing component is generated as a result that reflected return light from the at least one optical function element reenters the semiconductor laser, and a second contributing component is generated independent of intensity of an optical signal inputted to the optical receiver; and
wherein a reflectance of a front-end surface of the semiconductor laser is set to a value within a predetermined range including a reflectance that maximizes, in relation to change in the reflectance, the signal-to-noise ratio due to the first contributing component and the second contributing component.

2. The optical transmitter according to claim 1, wherein a gain region of the semiconductor laser comprises quantum dots.

3. The optical transmitter according to claim 1, wherein the reflectance of the front-end surface of the semiconductor laser is 2-25%.

4. The optical transmitter according to Claim 1, wherein the quantity of the reflected return signal, which is re-incident on the semiconductor laser, is less than 1.

5. The optical transmitter according to claim 1, wherein the optical transmitter comprises a refractive index adjusting agent between the front-end surface of the semiconductor laser and the at least one optical function element.

6. The optical transmitter according to claim 1, wherein the semiconductor laser and the at least one optical function element are integrated on a silicon substrate.
